(19) United States
(12) Patent Application Publication
(10) Pub. No.: US 2014/0284795 A1
(43) Pub. Date: Sep. 25, 2014

(54) SEMICONDUCTOR PACKAGE AND METHOD FOR MANUFACTURING THE SAME

(71) Applicant: SK hynix Inc., Icheon-si Gyeonggi-do (KR)

(72) Inventors: Sang Eun LEE, Icheon-si Gyeonggi-do (KR); Chang Il KIM, Busan (KR)

(73) Assignee: SK hynix Inc., Icheon-si Gyeonggi-do (KR)

(21) Appl. No.: 14/011,930

(22) Filed: Aug. 28, 2013

(30) Foreign Application Priority Data
Mar. 20, 2013 (KR) 10-2013-0029536

(51) Int. Cl. H01L 23/00

(52) U.S. Cl. CPC H01L 24/06; H01L 24/14; H01L 24/83
USPC 257/738; 257/786; 438/118

(57) ABSTRACT

Various embodiments are directed to a semiconductor package and a method for manufacturing the same. A semiconductor package includes the following: a substrate having a plurality of connection pads; a semiconductor chip provided with a plurality of bonding pads on a first surface thereof and attached onto the substrate in a face-down position so that the bonding pads are positioned right above the corresponding connection pads; and thermoplastic conductive members introduced between the substrate and the semiconductor chip such that the bonding pad and the corresponding connection pad may be electrically connected.

### CROSS-REFERENCE TO RELATED APPLICATIONS

The present application claims priority to Korean patent application number 10-2013-0029536 filed on Mar. 20, 2013, in the Korean Intellectual Property Office, which is incorporated herein by reference in its entirety.

### BACKGROUND

1. Technical Field

The present invention relates generally to a semiconductor technology, and more particularly, to a semiconductor package and a method for manufacturing the same.

2. Related Art

Recent trends in the electronic industry are based on manufacturing products in such a way as to accomplish weight reduction, device miniaturization, high speed operation, multi-functionality, high performance, high reliability, and low manufacturing cost. Therefore, package assembling technology is considered an important technology in product design.

The package assembling technology is used to protect a semiconductor chip, formed with integrated circuits, from external environment and to allow the semiconductor chip to be easily mounted on a substrate, thereby ensuring the semiconductor chip's reliability in operation. In such package assembling technology, a wire bonding process or flip chip bonding process is used to connect a semiconductor chip with a substrate.

In a wire bonding process, a bonding pad of a semiconductor and a connection pad of a substrate are connected using a wire. However, wire bonding process may cause problems such as wire sweeping, short-circuiting between wires, wire sagging, and the like. The wire bonding process has further problems such as high manufacturing costs due to the use of gold as the wire material, increase in process time due to the physical process of connecting the wire to respective bonding pads and connection pads, and lower operation speeds due to high inductance of the wires. Moreover, the wire bonding process has problems with increased package thickness due to a wire loop, reduction in mounting density, and design margin of the mother board.

In a flip chip bonding process, a bonding pad of a semiconductor and a connection pad of a substrate are connected using a bump formed on the bonding pad. Unfortunately, a flip chip bonding process increases the manufacturing cost due to an increase in wafer processing time required in forming bumps on a semiconductor chip. Additionally, a flip chip bonding process causes damage to the bumps due to the stress caused by difference in coefficient of thermal expansion between a semiconductor chip and a substrate. Furthermore, in a flip chip bonding process, an underfill resin is filled in a gap between a semiconductor chip and a substrate in order to prevent bumps from being damaged. However, since the gap between the semiconductor chip and the substrate is very narrow, a void may form when the underfill resin is filled in the gap, causing a void crack, thereby lowering the product's reliability. Furthermore, a flip chip bonding process causes the bumps to become invisible as the underfill resin is filled in the gap, making visible inspection on the connection status of the bumps impossible.

### SUMMARY

Various embodiments are generally directed to a semiconductor package capable of being manufactured with simple processes and having improved mechanical and electrical reliability, and a method for manufacturing the same.

In an embodiment of the present invention, a semiconductor package includes: a substrate having a plurality of connection pads; a semiconductor chip provided with a plurality of bonding pads on a first surface thereof and attached onto the substrate in a face-down position so that the bonding pads are positioned right above the corresponding connection pads; and thermoplastic conductive members introduced between the substrate and the semiconductor chip such that the bonding pad and the corresponding connection pad may be electrically connected.

The thermoplastic conductive members may include solder balls.

The substrate may include a plurality of grooves formed on a first surface which faces the semiconductor chip. The connection pads may be formed on the bottom of the respective grooves.

The thermoplastic conductive members may be introduced into the respective grooves, filling the grooves and projecting over the first surface of the substrate.

The semiconductor package may further include an adhesive member formed between the substrate and the first surface of the semiconductor chip such that the substrate and the semiconductor chip are attached to each other. The adhesive member may be cut on both edges in a saw-toothed shape to form a plurality of recesses so that the recesses of the adhesive member expose the respective connection pads of the substrate.

The semiconductor package may further include a gap retaining member embedded in the adhesive member.

In an embodiment of the present invention, a method for manufacturing a semiconductor package may include: providing a substrate having connection pads; attaching a semiconductor chip formed with a plurality of bonding pads on a first surface onto the substrate in a face-down position so that the bonding pads are positioned right above the corresponding connection pads; attaching thermoplastic conductive members outside the semiconductor chip on the substrate; and thermally blowing the thermoplastic conductive members to introduce the thermoplastic members between the substrate and the semiconductor chip such that the connection pad and the corresponding bonding pad are electrically connected.

Attaching the semiconductor chip onto the substrate may be performed by an adhesive member positioned in between the substrate and the semiconductor chip.

The method may further include dotting flux outside the semiconductor chip on the substrate before attaching the thermoplastic conductive members.

The method may further include hardening and removing the thermoplastic conductive members after thermally blowing the thermoplastic conductive members.

An electronic system including a controller, an interface, an input/output unit, and a memory device coupled with one another through a bus, the memory device including a semiconductor package may comprise: a substrate having a plurality of connection pads; a semiconductor chip provided with a plurality of bonding pads on a first surface thereof and attached onto the substrate in a face-down position so that the bonding pads are positioned right above the corresponding connection pads; and thermoplastic conductive members introduced between the substrate and the semiconductor chip such that the bonding pad and the connection pad corresponding thereto may be electrically connected.

A memory system may comprise: a memory controller; and a memory device including a semiconductor package comprising: a substrate having a plurality of connection pads; a semiconductor chip provided with a plurality of bonding pads on a first surface thereof and attached onto the substrate in a face-down position so that the bonding pads are positioned right above the corresponding connection pads; and thermoplastic conductive members introduced between the substrate and the semiconductor chip such that the bonding pad and the connection pad corresponding thereto may be electrically connected.

A computing system may comprise: a central processing unit; random access memory; an input device; and a memory system having a memory device including a semiconductor package comprising: a substrate having a plurality of connection pads; a semiconductor chip provided with a plurality of bonding pads on a first surface thereof and attached onto the substrate in a face-down position so that the bonding pads are positioned right above the corresponding connection pads; and thermoplastic conductive members introduced between the substrate and the semiconductor chip such that the bonding pad and the connection pad corresponding thereto may be electrically connected.

### BRIEF DESCRIPTION OF THE DRAWINGS

FIG. 1 is a cross-sectional view illustrating a semiconductor package in accordance with an embodiment of the present invention.

FIG. 2 is a plan view illustrating a substrate shown in FIG. 1.

FIGS. 3 to 6 are cross-sectional views illustrating the process of manufacturing the semiconductor package in accordance with an embodiment of the present invention.

FIG. 7 is a cross-sectional view illustrating a semiconductor package in accordance with an embodiment of the present invention.

FIG. 8 is a plan view illustrating a substrate and an adhesive member shown in FIG. 7.

FIGS. 9 to 14 are cross-sectional views illustrating the process of manufacturing the semiconductor package in accordance with an embodiment of the present invention.

FIG. 15 is a cross-sectional view illustrating a semiconductor package in accordance with an embodiment of the present invention.

FIGS. 16 to 18 are cross-sectional views illustrating the process of manufacturing the semiconductor package in accordance with an embodiment of the present invention.

FIG. 19 is a perspective view illustrating an electronic apparatus having the semiconductor package in accordance with various embodiments of the present invention.

FIG. 20 is a system block diagram showing an electronic system to which the semiconductor package in accordance with various embodiments of the present invention is applied.

FIG. 21 is a block diagram illustrating a memory system according to one embodiment of the present invention.

FIG. 22 is a view illustrating a computing system according to one embodiment of the present invention.

### DETAILED DESCRIPTION

Hereafter, various embodiments of the present invention will be described in detail with reference to the accompanying drawings.

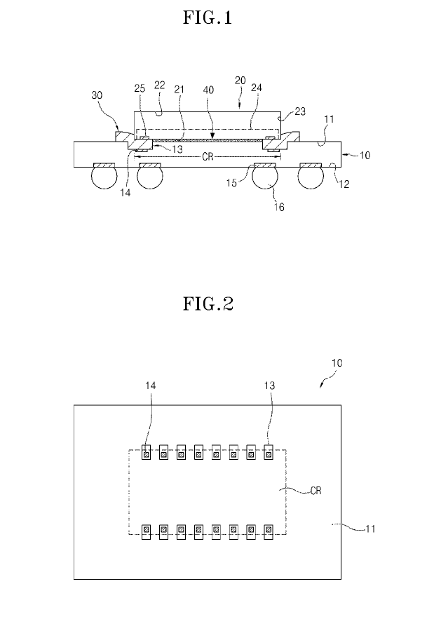

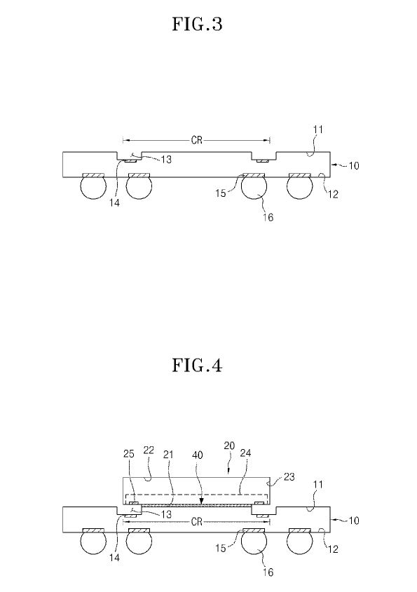

FIG. 1 is a cross-sectional view illustrating a semiconductor package in accordance with an embodiment of the present invention, and FIG. 2 is a plan view illustrating a first surface of a substrate shown in FIG. 1.

Referring to FIGS. 1 and 2, a semiconductor package in accordance with an embodiment of the present invention may comprise a substrate 10, a semiconductor chip 20, and a thermoplastic conductive member 30. The semiconductor package in accordance with an embodiment of the present invention may further comprise an adhesive member 40.

The substrate 10 may have a first surface 11 and a second surface 12 which is opposite to the first surface 11. The substrate 10 may include a plurality of grooves 13 and a plurality of connection pads 14. The substrate 10 may include ball lands 15 and external connection terminals 16.

A chip mounting region CR for attaching a semiconductor chip 20 thereto is defined on the first surface 11 of the substrate 10. A plurality of grooves 13 may be formed on the surface of the chip mounting region CR, along both edges of the chip mounting region CR. In order to allow the thermoplastic conductive members 30, which will be described later, to be smoothly introduced into the insides of the grooves 13, each of the grooves 13 may extend outside of the chip mounting region CR, and one end of each groove 13 may be placed outside the chip mounting region CR.

The connection pads 14 may be formed on the bottom of the respective grooves 13 in the chip mounting region CR. The ball lands 15 may be formed on the second surface 12 of the substrate 10. External connection terminals 16 such as solder balls may be attached onto the ball lands 15. Though not shown, the substrate 10 may include a plurality of wiring layers, the layers themselves being connected through vias. The connection pads 14 and the ball lands 15 may be electrically connected by way of the wiring layers and vias.

The semiconductor chip 20 may have a first surface 21, a second surface 22, side surfaces 23, a circuit unit 24, and a plurality of bonding pads 25.

The first surface 21 is opposite to the second surface 22 and the side surfaces 23 connect the first surface 21 with the second surface 22. The circuit unit 24 may include a data storage section for storing data and a data processing section for processing the data, and may consist of semiconductor elements, e.g. transistors, capacitors, fuses and the like, that are required for the operation of the chip. The bonding pads 25 serve as electrical contacts of the circuit unit 24 electrically connecting the circuit unit 24 with the outside, and are formed in the first surface 21 of the semiconductor chip 20 along both edges of the semiconductor chip 20.

The semiconductor chip 20 is attached onto the chip mounting region CR in a face-down position so that the bonding pads 25 correspond to the respective grooves 13 of the substrate 10.

The adhesive member 40 may be formed between the chip mounting region CR of the substrate 10 and the first surface 21 of the semiconductor chip 20 such that the substrate 10 and the semiconductor chip 20 are attached to each other. The adhesive member 40 may be a nonconductive adhesive tape or a nonconductive adhesive paste.

The thermoplastic conductive members 30 may flow into the respective grooves 13 such that the connection pad 14 and corresponding the bonding pad 25 are electrically connected with each other. In an embodiment, the thermoplastic conductive members 30 fill in the grooves 13 and are projected over the first surface 11 of the substrate 10. The thermoplastic conductive members 30 may be formed of a solder ball. Although the thermoplastic conductive members 30 are described and shown as being formed of a solder ball in an embodiment, material for the thermoplastic conductive members 30 is not limited to the solder ball, and any conductive material can be used provided that the conductive material is heated and/or melted to have a lowered viscosity and is then cooled down and/or rehardened.

Hereafter, a method for manufacturing the semiconductor package in accordance with an embodiment of the present invention depicted in FIGS. 1 and 2 will be described.

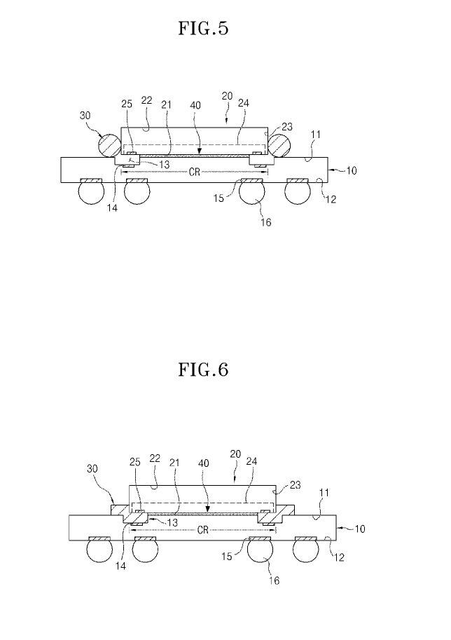

FIGS. 3 to 7 are cross-sectional views illustrating the process of manufacturing the semiconductor package in accordance with an embodiment of the present invention.

Referring to FIG. 3, there is provided a substrate 10 having a first surface 11 and a second surface 12 which is opposite to the first surface 11. The substrate 10 is formed with a plurality of grooves 13 along both edges of a chip mounting region CR defined on the first surface 11 and connection pads 14 on the bottom of the respective grooves 13.

The substrate 10 may include ball lands 15 formed on the second surface 12 and external connection terminals 16 attached onto the respective ball lands 15. Though not shown, the substrate may include a plurality of wiring layers and, the layers themselves being connected through vias. The connection pads 14 and the ball lands 15 may be electrically connected by way of the wiring layers and vias.

In order to allow the thermoplastic conductive members 30, which will be described later, to be smoothly introduced into the insides of the grooves 13, each of the grooves 13 may extend outside of the chip mounting region CR and one end of each groove 13 may be placed outside the chip mounting region CR.

Referring to FIG. 4, the semiconductor chip 20 formed with a plurality of bonding pads 25 along both edges of the first surface 21, corresponding to the respective grooves 13 of the substrate 10, is attached onto the chip mounting region CR of the substrate 10 in a face-down position by medium of an adhesive member 40. A nonconductive adhesive tape or a nonconductive adhesive paste may be used as the adhesive member 40. Reference number 24 denotes a circuit unit.

Referring to FIG. 5, for example, a flux (not shown) is dotted outside the semiconductor chip 20 on the first surface 11 of the substrate 10 such that the flux may correspond to the grooves 13 and connection pads 14. The thermoplastic conductive members 30 are then attached onto the periphery of each groove 13 by the medium of the flux. In an embodiment of the present invention, a solder ball may be used as the thermoplastic conductive members 30, and the solder ball is formed in such a way that the groove 13 is completely filled with the solder ball. Although the thermoplastic conductive members 30 are described and shown as being formed of a solder ball, material for the thermoplastic conductive members 30 is not limited to the solder ball, and any conductive material can be used provided that the conductive material is heated and/or melted to have a lowered viscosity and is then cooled down and/or rehardened according to an embodiment of the present invention.

Referring to FIG. 6, the thermoplastic conductive members 30 are subjected to thermal blowing. As the thermal blowing is performed, the thermoplastic conductive members 30 are melted and the molten thermoplastic conductive members 30 flow into the inside of their adjacent grooves such that the connection pad 14 and the corresponding bonding pad 25 are electrically connected with each other.

Though not shown, the thermoplastic conductive members 30 are then hardened through a cooling process, and a deflux process is performed afterwards to remove the flux covering the thermoplastic conductive members 30. The deflux process may be performed in such a way as to remove the flux stuck to the surface of the thermoplastic conductive members 30 by spraying de-ionized water (DI water) on the thermoplastic conductive members 30 as the substrate 10 passes through a deflux machine.

Although not shown, after the deflux process is completed, the method for manufacturing a semiconductor package in accordance with an embodiment of the present invention may further comprise the formation of an encapsulating member on the first surface 11 of the substrate 10 such that the encapsulating member covers the semiconductor chip 20 to protect the semiconductor chip 20 from the external environment.

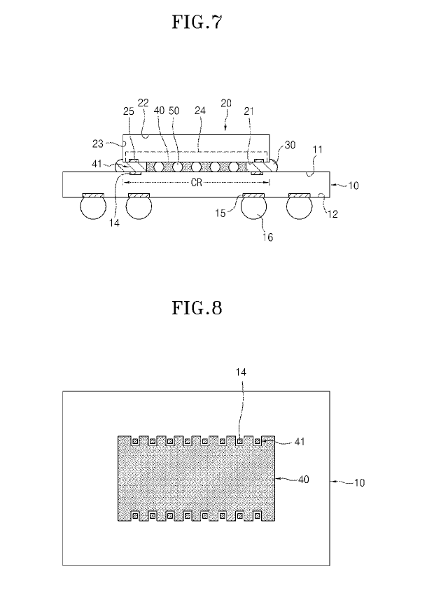

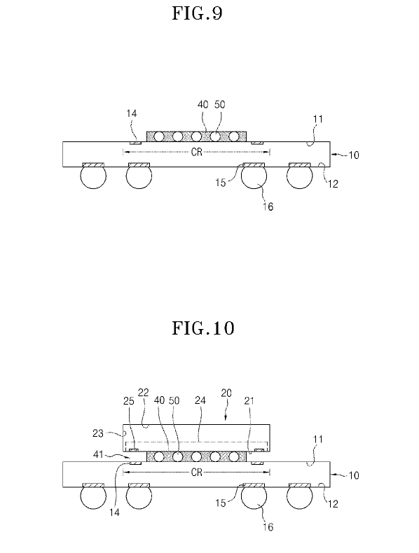

FIG. 7 is a cross-sectional view illustrating a semiconductor package in accordance with an embodiment of the present invention, and FIG. 8 is a plan view illustrating a substrate and an adhesive member shown in FIG. 7.

Referring to FIG. 7, a semiconductor package in accordance with an embodiment of the present invention may comprise a substrate 10, a semiconductor chip 20, a thermoplastic conductive member 30, an adhesive member 40, and a gap retaining member 50.

The substrate 10 may have a first surface 11 and a second surface 12 which is opposite to the first surface 11. The substrate 10 may include a plurality of connection pads 14 formed on the first surface 11. The substrate 10 may further include ball lands 15 formed on the second surface 12 and external connection terminals 16 attached onto the respective ball lands 15. For example, a solder ball may be used as the external connection terminals 16. A chip mounting region CR for attaching the semiconductor chip 20 thereto is defined on the first surface 11 of the substrate 10. A plurality of connection pads 14 are formed on the chip mounting region CR along both edges of the chip mounting region CR. Though not shown, the substrate 10 may include a plurality of wiring layers, the layers themselves being connected through vias. The connection pads 14 and the ball lands 15 may be electrically connected by way of the wiring layers and vias.

The adhesive member 40 is formed on the chip mounting region CR of the substrate such that it exposes the connection members 14 of the substrate 10. The adhesive member 40 may be formed by cutting both edges of the adhesive member 40 in a saw-toothed shape such that a plurality of recesses 41, each recess exposing the individual connection pad 14, is formed at both sides of the substrate. Accordingly, the adhesive member 40 is attached onto the chip mounting region CR of the substrate 10 such that each of the recesses 41 exposes the corresponding connection pad 14. A nonconductive adhesive film or a nonconductive adhesive paste may be used as the adhesive member 40.

The gap retaining member 50 is employed within the adhesive member 40 in order to ensure the space between the substrate 10 and the semiconductor chip 20 and is formed.

The semiconductor chip 20 has a first surface 21, a second surface 22 and side surfaces 23, and includes a circuit unit 24 and a plurality of bonding pads 25. The first surface 21 is opposite to the second surface 22, and the side surfaces 23 connect the first surface 21 with the second surface 22. The circuit unit 24 may include a data storage section for storing data and a data processing section for processing the data. The circuit unit 24 may consist of semiconductor elements, e.g. transistors, capacitors, fuses and the like, that are required for the operation of the chip.

The bonding pads 25 serve as electrical contacts of the circuit unit 24 electrically connecting the circuit unit 24 with the outside, and are formed in the first surface 21 of the semiconductor chip 20 along both edges of the semiconductor chip 20.

The semiconductor chip 20 is attached onto the chip mounting region CR in a face-down position such that the bonding pads 25 correspond to the respective connection pads 14 of the substrate 10.

The thermoplastic conductive members 30 may flow into the recesses 41 of the adhesive member 40 such that the connection pad 14 of the substrate 10 and the bonding pad 25 of the corresponding semiconductor chip 20 are electrically connected with each other. The thermoplastic conductive members 30 may be formed of a solder ball. Although the thermoplastic conductive members 30 are described and shown as being formed of a solder ball in an embodiment of the present invention, a material for the thermoplastic conductive members 30 is not limited to the solder ball, and any conductive material can be used provided that the conductive material is heated and/or melted to have a lowered viscosity and is then cooled down and/or rehardened.

Hereafter, a method for manufacturing the semiconductor package in accordance with an embodiment of the present invention depicted in FIGS. 7 and 8 will be described.

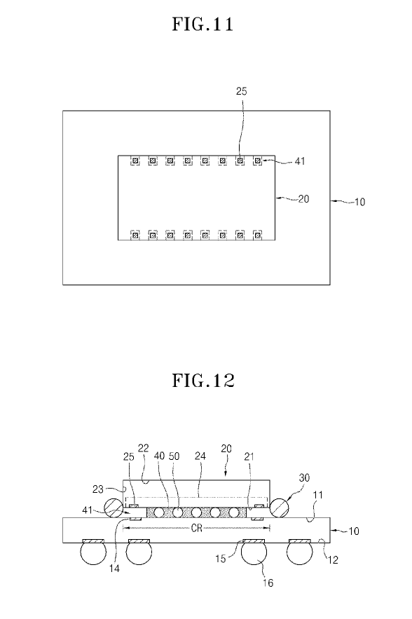

FIGS. 9 to 14 are cross-sectional views illustrating the processes steps of manufacturing the semiconductor package in accordance with an embodiment of the present invention.

Referring to FIG. 9, a substrate 10 is provided with a chip mounting region CR defined on a first surface 11 thereof and formed with a plurality of connection pads 14 along both edges of the chip mounting region CR.

The substrate 10 may include ball lands 15 formed on the second surface 12, which is opposite to the first surface 11, and external connection terminals 16, e.g. solder balls on the respective ball lands 15. Though not shown, the substrate 10 may include a plurality of wiring layers, the layers themselves being connected through vias. The connection pads 14 and the ball lands 15 may be electrically connected by way of the wiring layers and vias.

Next, the adhesive member 40, with a plurality of recesses 41, each corresponding to the individual connection pad 14 of the substrate 10, is attached onto the chip mounting region CR of the substrate 10 such that each of the recesses 41 exposes the corresponding connection pad 14. A nonconductive adhesive film or a nonconductive adhesive paste may be used as the adhesive member 40 and a gap retaining member 50 may be embedded in the adhesive member 40.

Referring to FIGS. 10 and 11, a semiconductor chip 20 formed with a plurality of bonding pads 25 along both edges of the surface 21 is attached onto the chip mounting region CR in a face-down position by medium of the adhesive member 40 such that the bonding pads 25 correspond to the respective recesses 41 of the adhesive member 40.

Referring to FIGS. 12 and 13, a flux (not shown) is dotted outside the semiconductor chip 20 on the first surface 11 of the substrate 10 so that the flux may correspond to the connection pads 14. The thermoplastic conductive members 30 are then attached by the medium of the flux. In an embodiment of the present invention, a solder ball may be used as the thermoplastic conductive member. Although the thermoplastic conductive members 30 are described and shown as being formed of a solder ball in an embodiment of the present invention, a material for the thermoplastic conductive members 30 is not limited to the solder ball, and any conductive material can be used provided that the conductive material is heated and/or melted to have a lowered viscosity and is then cooled down and/or rehardened.

Referring to FIG. 14, the thermoplastic conductive members 30 are subject to thermal blowing. As the thermal blowing is performed, the thermoplastic conductive members 30 are melted and guided inside their adjacent recesses such that the connection pad 14 and bonding pad 25 corresponding thereto are electrically connected with each other.

Though not shown, the thermoplastic conductive members 30 are then hardened through a cooling process, and a deflux process is performed afterwards to remove the flux covering the thermoplastic conductive members 30. The deflux process may be performed in such a way as to remove the flux stuck to the surface of the thermoplastic conductive members 30 by spraying DI water on the thermoplastic conductive members as the substrate 10 passes through a deflux machine.

Although not shown, after the deflux process is completed, the method for manufacturing a semiconductor package in accordance with an embodiment of the present invention may further comprise the formation of an encapsulating member on the first surface 11 of the substrate 10 such that the encapsulating member covers the semiconductor chip 20 to protect the semiconductor chip 20 from the external environment.

As described above, since the connection pads and the bonding pads of the semiconductor chip are electrically connected by introducing the thermoplastic conductive members into the space between the substrate and the semiconductor chip by way of the thermal blowing, the use of conventional wires becomes unnecessary. In doing so, the present invention provides significant and novel solutions to the problematic reliability and other issues associated with the use of conventional wires such as poor shape of wires, increase in production cost due to the use of expensive gold wires, delay in process time due to physically connecting the wire to the respective bonding pads and connection pads, lowering of the operation speed due to high inductance of the wire, increase in package size due to the wire loop (resulting from the reduction in the mounting density and design margin of the mother board), and increase in the production cost due to the formation of bumps and void cracks.

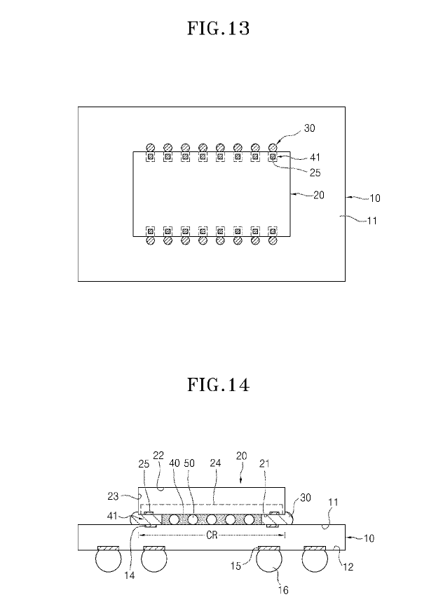

FIG. 15 is a cross-sectional view illustrating a semiconductor package in accordance with an embodiment of the present invention.

Referring to FIG. 15, a semiconductor package in accordance with an embodiment of the present invention may comprise a substrate 10, a semiconductor chip 20, and a thermoplastic conductive member 30. The semiconductor package in accordance with an embodiment of the present invention may further comprise an adhesive member 40.

The substrate 10 may have a first surface 11 and a second surface 12 which is opposite to the first surface 11. The substrate 10 may include a plurality of connection pads 14. The substrate 10 may further include ball lands 15 and external connection terminals 16. A chip mounting region CR for attaching the semiconductor chip 20 thereto is defined on the first surface 11 of the substrate 10. A plurality of connection pads 14 are formed outside the chip mounting region CR on the first surface 11 along both edges of the chip mounting region CR.

The ball lands 15 are formed on the second surface 12 of the substrate 10 and the external connection terminals 16 are attached onto the respective ball lands 15. For example, a solder ball may be used as the external connection terminals 16. Though not shown, the substrate 10 may include a plurality of wiring layers, the layers themselves being connected through vias. The connection pads 14 and the ball lands 15 may be electrically connected by way of the wiring layers and vias.

The semiconductor chip 20 may have a first surface 21, a second surface 22 and side surfaces 23, and may include a circuit unit 24 and bonding pads 25. The first surface 21 is opposite to the second surface 22, and the side surfaces 23 connect the first surface 21 with the second surface 22. The circuit unit 24 may include a data storage section for storing data and a data processing section for processing data, and may consist of semiconductor elements, e.g. transistors, capacitors, fuses and the like, that are required for the operation of the chip. The bonding pads 25 serve as electrical contacts of the circuit unit 24 for electrical connection of the circuit unit 24 with the outside, and are formed in the first surface 21 of the semiconductor chip 20 along both edges of the semiconductor chip 20. The semiconductor chip 20 is attached onto the chip mounting region CR in a face-up position by medium of the adhesive member 40 such that the bonding pads 25 are elevated and adjacent to the corresponding connection pads 14.

A plurality of thermoplastic conductive member 30 may be formed along both edges of the semiconductor chip 20 such that the bonding pad 25 and the corresponding connection pads 14 may be connected with each other. Although the thermoplastic conductive members 30 are described and shown as being formed of a solder ball in an embodiment of the present invention, material for the thermoplastic conductive members is not limited to the solder ball, and any conductive material can be used provided that the conductive material is heated and/or melted to have a lowered viscosity and is then cooled down and/or rehardened.

Hereafter, a method for manufacturing the semiconductor package in accordance with an embodiment of the present invention depicted in FIG. 15 will be described.

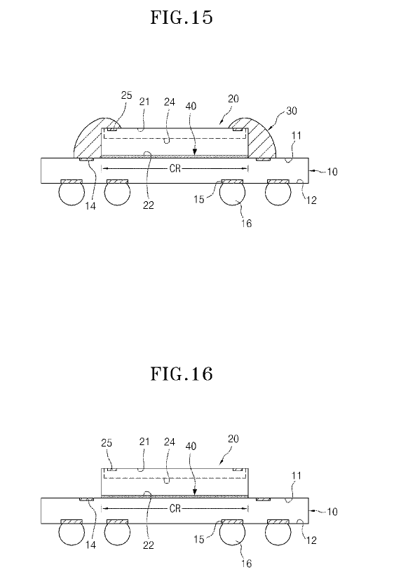

FIGS. 16 to 18 are cross-sectional views illustrating the process of manufacturing the semiconductor package in accordance with an embodiment of the present invention.

Referring to FIG. 16, there is provided a substrate 10 having a first surface 11 which defines a chip mounting region CR thereon and formed with a plurality of connection pads 14 outside the chip mounting region CR on the first surface 11 along both edges of the chip mounting region CR. The substrate 10 may include ball lands 15 formed on a second surface which is opposite to the first surface 11 and external connection terminals 16, e.g. solder balls on the respective ball lands 15. Though not shown, the substrate 10 may include a plurality of wiring layers, the layers themselves being connected through vias and the connection pads 14 and the ball lands 15 may be electrically connected by way of the wiring layers and vias.

a semiconductor chip 20 formed with a plurality of bonding pads 25 along both edges of the surface 21 is attached onto the chip mounting region CR in a face-up position by medium of an adhesive member 40 such that the bonding pads 25 are elevated and adjacent to the corresponding connection pads 14 of the substrate 10. A nonconductive adhesive film or a nonconductive adhesive paste may be used as the adhesive member 40.

Referring to FIG. 17, a flux (not shown) is dotted on the connection pads 14 of the substrate 10, and the thermoplastic conductive members 30 are then attached onto the respective connection pads 14 by the medium of the flux. In an embodiment of the present invention, a solder ball may be used as the thermoplastic conductive members 30. Although the thermoplastic conductive members 30 are described and shown as being formed of a solder ball in an embodiment of the present invention, material for the thermoplastic conductive members 30 is not limited to the solder ball, and any conductive material can be used provided that the conductive material is heated and/or melted to have a lowered viscosity and is then cooled down and/or rehardened.

Referring to FIG. 18, the thermoplastic conductive members 30 are subject to thermal blowing such that the connection pad 14 and bonding pad 25 corresponding thereto are electrically connected with each other. As the thermal blowing is performed, the thermoplastic conductive members 30 are melted and the molten thermoplastic conductive members 30 are attached to the first surface 21 of the semiconductor ship 20 including the bonding pads 25, the side surfaces 23 of the semiconductor chip 20 and the first surface 11 of the substrate 10 including the connection pads 14 such that the connection pad 14 and the bonding pad 25 corresponding thereto are electrically connected with each other.

Though not shown, the thermoplastic conductive members 30 are then hardened through a cooling process, and a deflux process is performed afterwards to remove the flux covering the thermoplastic conductive members 30. The deflux process may be performed in such a way as to remove the flux stuck to the surface of the thermoplastic conductive members 30 by spraying DI water on the thermoplastic conductive members as the substrate 10 passes through a deflux machine. Although not shown, after the deflux process is completed, a process of forming an encapsulating member on the first surface 11 of the substrate 10 may be performed such that the encapsulating member covers the semiconductor chip 20 to protect the semiconductor chip 20 from the external environment.

The semiconductor device in accordance with various embodiments may be applied to a variety of electronic apparatuses.

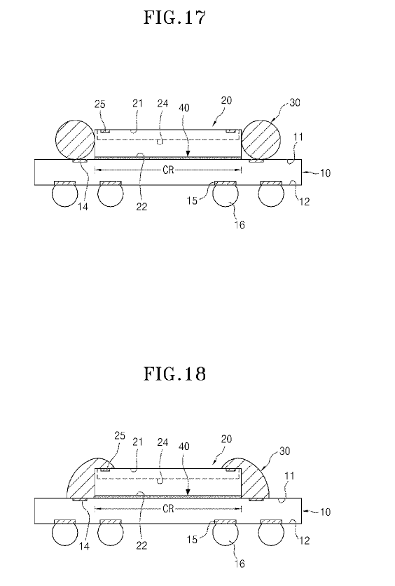

FIG. 19 is a perspective view illustrating an electronic apparatus having the semiconductor device in accordance with various embodiments.

As shown in FIG. 19, the semiconductor package in accordance with various embodiments may be applied to an electronic apparatus 1000 such as a mobile phone. The semiconductor package in accordance with various embodiments is important in improving cost competitiveness and reliability of the electronic apparatus 1000 since it can be manufactured at a low cost due to simpler processes and have improved mechanical and electrical reliability due to the materials used. The electronic apparatus 1000 is not limited to the mobile phone shown in FIG. 19, and may include various electronic appliances, such as a mobile electronic appliance, a laptop computer, a notebook computer, a portable multimedia player (PMP), an MP3 player, a camcorder, a web tablet, a wireless phone, a navigator, a personal digital assistant (PDA), and so forth.

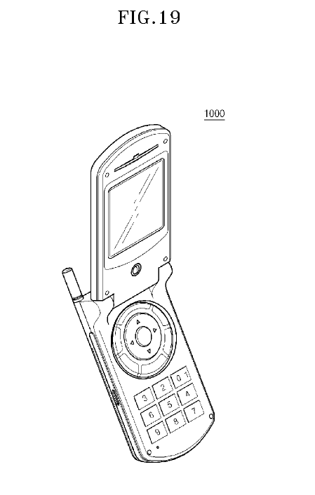

FIG. 20 is an example of a block diagram showing an electronic system which may include the semiconductor package according to various embodiments.

As shown in FIG. 20, an electronic system 1300 may include a controller 1310, an input/output unit 1320, and a memory device 1330. The controller 1310, the input/output unit 1320 and the memory device 1330 may be coupled with one another through a bus 1350. The bus 1350 serves as a path through which data move.

For example, the controller 1310 may include at least any one of the following: one or more microprocessors, one or more digital signal processors, one or more microcontrollers, and logic devices capable of performing the same functions as these components. The memory device 1330 may include the semiconductor package according to various embodiments of the present invention. The input/output unit 1320 may include at least one selected among a keypad, a keyboard, a display device, and so forth. The memory device 1330 is a device for storing data. The memory device 1330 may store data and/or commands to be executed by the controller 1310 and the like.

The memory device 1330 may include a volatile memory device and/or a nonvolatile memory device, such as a flash memory. For example, a flash memory to which the technology of the present invention is applied may be mounted to an information processing system such as a mobile terminal or a desktop computer. The flash memory may be constituted by a solid state drive (SSD). In this case, the electronic system 1300 may stably store a large amount of data in a flash memory system.

The electronic system 1300 may further include an interface 1340 configured to transmit and receive data to and from a communication network. The interface 1340 may be a wired or wireless type. For example, the interface 1340 may include an antenna or a wired (or wireless) transceiver. Furthermore, though not shown, a person skilled in the art will readily appreciate that the electronic system 1300 may additionally include an application chipset, a camera image processor (CIP), an input/output unit, etc.

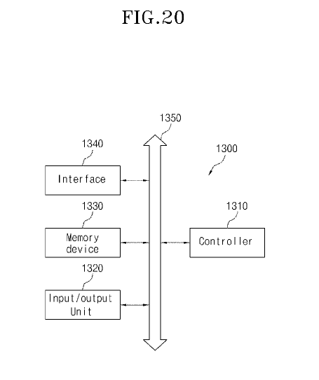

FIG. 21 is a block diagram illustrating a memory system according to one embodiment of the present invention.

In FIG. 21, the memory system 100 of the present embodiment may include a memory device 120 and a memory controller 110.

The memory device 120 may serve as a volatile memory device such as a dynamic random-access memory (DRAM) or a nonvolatile memory device such as a magnetoresistive RAM (MRAM), spin torque transfer MRAM (STT-MRAM), phase-change RAM (PCRAM), resistive RAM (ReRAM), or ferroelectric RAM (FeRAM). The memory device 120 may include the semiconductor package according to various embodiments of the present invention.

The memory controller 110 may control the memory device 120, and may include a static random-access memory (SRAM) 111, a central processing unit (CPU) 112, a host interface 113, an error correction code block (ECC) 114 and a memory interface 115. The SRAM 111 is used as an operation memory of the CPU 112, the CPU 112 performs control operation for data exchange of the memory controller 110, and the host interface 113 has data exchange protocol of a host accessed to the memory system 100. The ECC 114 detects and corrects error of data read from the memory device 120, and the memory interface 115 interfaces with the semiconductor memory device 120. The memory controller 110 may further include read-only memory (ROM) for storing data for interfacing with the host, etc.

The memory system 100 may be used as a memory card or a solid state disk SSD by combination of the memory device 120 and the memory controller 110. In the event that the memory system 100 is the SSD, the memory controller 110 communicates with an external device, e.g. host through one of various interface protocols such as USB, MMC, PCI-E, SATA, PATA, SCSI, ESDI, IDE, etc.

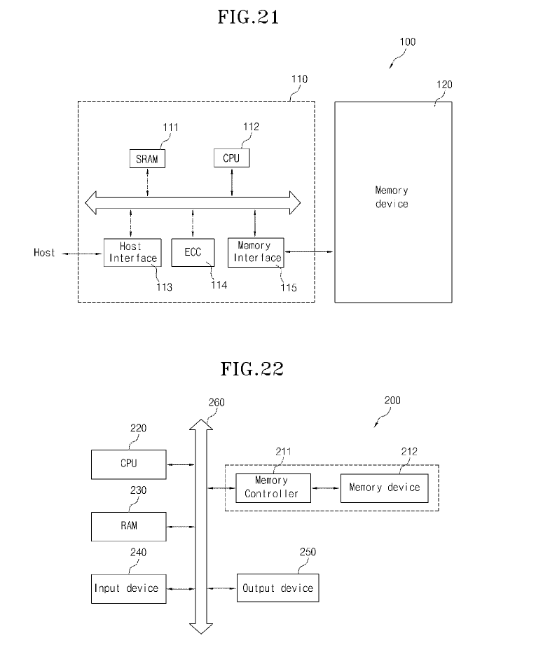

FIG. 22 is a view illustrating a computing system according to one embodiment of the present invention.

In FIG. 22, the computing system 200 of the present embodiment may include a CPU 220 connected electrically to a system bus 260, a RAM 230, an input device 240, an output device 250 and a memory system 210. In case that the computing system 200 is a mobile device, a battery (not shown) for supplying an operation voltage to the computing system 200 may be further provided. The computing system 200 of the present invention may further include an application chipset, a CMOS image processor CIS, a mobile DRAM, etc.

The output device or input device 240 may be a self-contained display in the case of a portable electronic device. The input device or output device 250 may be a physical keyboard or a virtual keyboard in the case of a portable electronic device such as i.e. a smartphone, tablet pc, labtop, etc. The portable electronic device may further include, without limitation, a trackball, touchpad, or other cursor control device combined with a selection control, such as a pushbutton, to select an item highlighted by cursor manipulation. The memory system 210 may include a memory device which comprises the semiconductor package according to various embodiments of the present invention as described in FIG. 21.

Although specific embodiments of the present invention have been described for illustrative purposes, those skilled in the art will appreciate that various modifications, additions and substitutions are possible without departing from the scope and the spirit of the invention as disclosed in the accompanying claims.

What is claimed is:

1. A semiconductor package comprising:
a substrate having a plurality of connection pads;
a semiconductor chip provided with a plurality of bonding pads on a first surface thereof and attached onto the substrate in a face-down position so that the bonding pads are positioned right above the corresponding connection pads; and
thermoplastic conductive members introduced between the substrate and the semiconductor chip such that the bonding pad and the connection pad corresponding thereto may be electrically connected.

2. The semiconductor package according to claim 1, wherein at least one of the thermoplastic conductive members is formed of a solder ball or a conductive material that is melted to have a lowered viscosity and then rehardened.

3. The semiconductor package according to claim 1,
wherein the substrate includes a plurality of grooves formed on a first surface which faces the semiconductor chip, and the connection pads are formed on the bottom of the respective grooves.

4. The semiconductor package according to claim 3, wherein the thermoplastic conductive members are introduced into the respective grooves such that they fill in the grooves and are projected over the first surface of the substrate.

5. The semiconductor package according to claim 1, further comprising:
an adhesive member formed between the substrate and the first surface of the semiconductor chip such that the substrate and the semiconductor chip are attached to each other.

6. The semiconductor package according to claim 5, further comprising:
a gap retaining member embedded in the adhesive member.

7. The semiconductor package according to claim 5, wherein the adhesive member includes both edges cut in a saw-toothed shape to form a plurality of recesses such that the recesses of the adhesive member expose the respective connection pads of the substrate.

8. A method for manufacturing a semiconductor package, comprising the steps of:
providing a substrate having connection pads;
attaching a semiconductor chip formed with a plurality of bonding pads on a first surface onto the substrate in a face-down position so that the bonding pads are positioned right above the corresponding connection pads, respectively;
attaching thermoplastic conductive members outside the semiconductor chip on the substrate; and
thermally blowing the thermoplastic conductive members to introduce the thermoplastic members between the substrate and the semiconductor chip such that the connection pad and the bonding pad corresponding thereto are electrically connected.

9. The method according to claim 8, wherein the thermoplastic conductive members include solder balls or any conductive material that is melted to have a lowered viscosity and then rehardened.

10. The method according to claim 8, wherein the substrate further includes a plurality of grooves formed on the first surface which faces the semiconductor chip, and the connection pads are formed on the bottom of the respective grooves.

11. The method according to claim 8, wherein attaching the semiconductor chip onto the substrate is performed by attaching the substrate and the semiconductor chip by the medium of an adhesive member.

12. The method according to claim 11, wherein the adhesive member includes both edges cut in a saw-toothed shape to form a plurality of recesses such that the recesses of the adhesive member expose the respective connection pads of the substrate,
wherein attaching the substrate and the semiconductor chip by the medium of an adhesive member includes the steps of:
attaching the adhesive member onto the substrate such that the recesses expose the corresponding connection pads; and
attaching the semiconductor chip onto the adhesive member such that the bonding pads correspond to the respective recesses.

13. The method according to claim 8, further comprising, before attaching the thermoplastic conductive members, the step of:
dotting flux outside the semiconductor chip on the substrate.

14. The method according to claim 13, further comprising, after thermally blowing the thermoplastic conductive members, the step of:
hardening the thermoplastic conductive members; and
removing the flux.

15. An electronic system including a controller, an interface, an input/output unit, and a memory device coupled with one another through a bus, the memory device including a semiconductor package comprising:
a substrate having a plurality of connection pads;
a semiconductor chip provided with a plurality of bonding pads on a first surface thereof and attached onto the substrate in a face-down position so that the bonding pads are positioned right above the corresponding connection pads; and
thermoplastic conductive members introduced between the substrate and the semiconductor chip such that the bonding pad and the connection pad corresponding thereto may be electrically connected.
